(19) United States
(12) Patent Application Publication
(10) Pub. No.: US 2025/0207239 A1
(43) Pub. Date: Jun. 26, 2025

(54) LIQUID METAL ALLOY FEED MATERIALS FOR ION IMPLANTATION

(71) Applicant: Axcelis Technologies, Inc., Beverly, MA (US)

(72) Inventors: Vladimir ROMANOV, Beverly, MA (US); Neil COLVIN, Beverly, MA (US); Ed MOORE, Beverly, MA (US); Udo VERKERK, Beverly, MA (US); Neil BASSOM, Beverly, MA (US); Kevin WENZEL, Beverly, MA (US)

(21) Appl. No.: 18/991,879

(22) Filed: Dec. 23, 2024

Related U.S. Application Data
(60) Provisional application No. 63/614,001, filed on Dec. 22, 2023.

(51) Int. Cl. C23C 14/48

(52) U.S. Cl. CPC C23C 14/48

(57) ABSTRACT

Liquid metal alloy precursor compositions and their use as liquid metal alloy ion sources for ion implantation of non-traditional source elements generally include liquid metal alloy precursor compositions having a melting point less than a maximum operating temperature for the ion implantation system of about 550° C. The liquid metal alloy precursor composition generally provides homogenous or heterogenous liquid metal alloys having eutectic melting temperature less than about 550° C. The heterogenous liquid metal alloy compositions include a flux metal having a relatively low melting point and at least one additional metal that is at least partially soluble in the flux metal at a selected operating temperature of less than about 550° C. The liquid metal alloy precursor compositions are suitable for use in ion implantation systems configured for liquid metal ion sources (LMIS) or capillary drive sources. Also disclosed are processes for implanting liquid metal alloy ion source precursor compositions.

### CROSS REFERENCE TO RELATED APPLICATIONS

This application claims the benefit of priority to U.S. Provisional Patent Application No. 63/614,001, filed Dec. 22, 2023, all of which are incorporated by reference in their entirety herein.

### BACKGROUND

The present disclosure generally relates to semiconductor ion implantation, and more specifically, to methods for selectively implanting ions extracted from heterogenous or homogenous liquid metal alloy compositions exhibiting a eutectic melting temperature suitable for use in ion implantation systems.

In the manufacture of semiconductor devices, ion implantation is used to dope semiconductors with impurities. For example, ion implantation systems are often utilized to dope a workpiece, such as a semiconductor wafer, with ions from an ion beam, in order to either produce n- or p-type material doping, or to form passivation layers during fabrication of an integrated circuit, Such beam treatment is often used to selectively implant the workpiece with impurities of a specified dopant material, at a predetermined energy level, and in controlled concentration, to produce a desired semiconductor material during fabrication of an integrated circuit. When used for doping a semiconductor wafer, for example, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

An ion implanter generally includes an ion source, an ion extraction device, a mass analysis device, a beam transport device and a workpiece processing device. The ion source generates ions of desired atomic or molecular dopant species. These ions are extracted from the ion source by an extraction system, such as a set of electrodes which energize and direct the flow of ions from the ion source, forming an ion beam. Desired ions are separated from the ion beam in a mass analysis device, such as a magnetic dipole that performs mass dispersion or separation of the extracted ion beam. The beam transport device, such as a vacuum system containing a series of focusing devices, transports the ion beam to the workpiece processing device while maintaining desired properties of the ion beam. Finally, workpieces such as semiconductor wafers are transferred in to and out of the workpiece processing device via a workpiece handling system, which may include one or more robotic arms for placing a workpiece to be treated in front of the ion beam and removing the treated workpiece from the ion implanter.

Two general approaches have been conventionally utilized to generate ions from ion sources if no suitable gases are available; namely, vaporizers and solid targets. For example, if a suitable salt or other compound containing the desired dopant element exists, it may be first heated in an oven in order to vaporize the element to its gaseous phase, and the vapor can be subsequently fed into the ion source chamber (i.e., arc chamber) via a communicating channel connecting the oven to the ion source chamber. Such an oven is commonly used when aluminum is selected as the ion species, whereby compounds such as aluminum iodide (AlI₃) or aluminum chloride (AlCl₃) may be utilized with the vaporizer. However, vaporizers generally have long warm-up and cool-down times, whereby extensive amounts of time (e.g., on the order of 20-30 minutes) can be taken to melt and/or vaporize the compound prior to the resultant vaporized material being fed into the ion source chamber, as well as a similar amount of time to transition to cool down, as no valving is typically present in the communicating channel between the oven and the ion source chamber.

Further, the material vaporized from the compounds can contain undesirable atoms, such as fluorine (F), chlorine (Cl) and oxygen (O), where the undesirable atoms can deleteriously reduce beam current and/or coat electrically active components of the ion implanter with by-products, thus potentially causing instabilities and shortening a lifetime of the ion source.

The other approach for generating ions from such species is to identify a compound of the element having a high melting point and providing the compound as a solid target within the ion source. For example, for aluminum ion species, a solid target of aluminum nitride (AlN) or aluminum oxide (Al₂O₃) is known to not melt at typical ion source temperatures. Such a target can be placed within the ion source chamber, where the target can be either held in the plasma column, located in a pocket in a sidewall of the ion source chamber, or held in the repeller of the ion source. Atoms of the desired element can then be brought into the plasma via physical sputtering or chemical etching of the target by a plasma generated in the ion source. Such approaches, however, are limited by the physical amount of solid source material that can be contained within the ion source, as well as that the additional atoms present in the target can reduce beam current or shorten the lifetime of the ion source by generating undesirable byproducts,

Another conventional technique is to place a metal-containing material inside the arc chamber. For aluminum implants, the metal-containing material may comprise aluminum oxide, aluminum fluoride, or aluminum nitride, all of which can withstand the approximately 800° C. temperatures of the plasma chamber. In such a system, atoms are removed from the metal-containing material, either through sputtering, chemical action, or a combination of these, and the atoms enter the plasma. Etchant gases such as fluorine can be further used for chemical etching of the material. While acceptable beam currents can be attained using these various techniques, compounds of aluminum oxide, aluminum chloride, and aluminum nitride, all of which are good electrical insulators, tend to be deposited on electrodes adjacent to the ion source in a relatively short period of time (e.g., 5-10 hours). As such, various deleterious effects are seen, such as high voltage instabilities and associated variations in dosage of ions being implanted.

### BRIEF SUMMARY

Disclosed herein are processes for implanting ions in a workpiece using a liquid metal alloy ion source, and liquid metal alloy precursor compositions.

In one or more embodiments, the process for implanting selected ions into a workpiece using a liquid metal alloy ion source includes heating a liquid metal precursor composition at an operating temperature of less than about 550° C. to form a homogeneous or heterogenous liquid metal alloy ion source; vaporizing and ionizing the homogeneous or heterogenous liquid metal alloy ion source in an arc chamber to create a plasma of ionized metal elements; extracting the ionized metal elements within the plasma through a source aperture to form an ion beam; and implanting one or more of the ionized metal elements into the workpiece.

In one or more embodiments, the liquid metal alloy precursor composition for ion implantation includes two or more metals having a eutectic melting point less than about 550° C. configured to form a homogeneous liquid metal alloy ion source in an arc chamber of an ion implantation system at an operating temperature greater than the eutectic melting temperature, vaporize, and ionize in a plasma source into a plurality of dopant ions.

In one or more embodiments, the liquid metal alloy precursor composition as an ion source for ion implantation includes a first metal and at least one additional metal configured to form a heterogeneous liquid metal alloy ion source in an arc chamber of an ion implantation system, vaporize, and ionize in a plasma source into a plurality of dopant ions, wherein the first metal is a liquid flux metal and the at least one additional metal is at least partially soluble in the liquid flux metal at an operating temperature of a crucible containing the liquid metal alloy precursor composition, wherein the operating temperature is less than about 550° C. and is above a melting temperature of the first metal.

These and other objects, advantages and features of the disclosure will become better understood from the detailed description of the disclosure that is described in conjunction with the accompanying drawings.

### BRIEF DESCRIPTION OF DRAWINGS

FIG. 1 is a block diagram of an exemplary vacuum system in accordance with several aspects of the present disclosure;

FIG. 2 is a schematic representation of an ion source in accordance with one example of the present disclosure;

FIG. 3 is a flowchart illustrating an example method for forming ions from a solid source material according to another example of the present disclosure;

FIG. 4 graphically illustrates mass peaks as a function of relative beam current from an ionized heterogenous aluminum-gallium alloy ion source mixture in accordance with the present disclosure; and

FIG. 5 graphically illustrates beam current as a function of time from a heterogenous aluminum-gallium metal alloy precursor composition in accordance with the present disclosure.

### DETAILED DESCRIPTION

The present disclosure is generally directed to liquid metal alloy precursor compositions and their use as ion sources for ion implantation of non-traditional source elements, including, but not limited to, at least one metal selected from the group of aluminum (Al), lanthanum (La), cerium (Ce), platinum (Pt), neodymium (Nd), germanium (Ge), bismuth (Bi), silver (Ag), lead (Pb), lithium (Li), tellurium (Te), zinc (Zn), strontium (Sr) magnesium (Mg), gold (Au), copper (Cu) samarium (Sm), europium (Eu), terbium (Tb), dysprosium (Dy), holmium (Ho), erbium (Er) ytterbium (Yb), gallium (Ga) indium (In), tin (Sn), and selenium (Se), various combinations thereof, and the like. The liquid metal alloy precursor compositions can be utilized in ion implantation systems configured with a reservoir fluidly coupled to an are chamber, wherein the liquid metal alloy precursor composition, in solid form, e.g., powder, particles or the like, is placed in a reservoir (i.e., crucible) and subsequently heated to form a liquid metal alloy composition. The liquid metal alloy precursor composition can be an alloy, individual metals, or combinations thereof. A liquid control apparatus can then be utilized to provide a controlled volume of the liquid metal alloy composition to the arc chamber, wherein it is subsequently ionized into a plurality of ions to form an ion beam that is directed at a workpiece.

As used herein, the term “alloy” generally refers to a metallic material that contains two or more elements, wherein at least one of the primary elements is a metal. As will be described in greater detail below, the liquid metal alloy precursor compositions can be configured to provide the arc chamber with homogenous liquid metal alloy compositions or heterogenous liquid metal alloy compositions. The term “homogenous liquid metal alloy composition” generally refers to a solid precursor composition that is heated to form a homogenous liquid alloy solution of the two or more elements at a specific temperature. The term “heterogenous liquid metal alloy composition” generally refers to a precursor composition that forms a mixture or dispersion upon heating at a specific temperature, wherein at least one metal is partially suspended in a metal-based solvent, i.e., one of the metals in the precursor composition functions as a flux material.

The homogenous and heterogenous liquid metal alloy compositions as the ion source provides advantages over conventional ion sources that use non-metal alloys as sputter targets within the conventional ion source or as feed materials in a vaporizer. Such conventional approaches generally have low beam currents and introduce atoms other than the desired dopant into the plasma within the conventional ion source. Moreover, the homogenous and heterogenous liquid metal alloy compositions provide a greater selection of dopant ions than previously possible. For example, recent advances in semiconductor fabrication have found aluminum to be useful in place of boron as a p-type dopant for power devices due to its low diffusivity in silicon carbide. Metals like lanthanum, indium, yttrium, iridium, gallium, and platinum are also under investigation for silicon devices and can be introduced as dopant ions using liquid metal alloy precursor compositions of these elements.

For the purposes of the description hereinafter, the terms “upper”, “lower”, “top”, “bottom”, “left,” and “right,” and derivatives thereof shall relate to the described structures, as they are oriented in the drawing figures. The same numbers in the various figures can refer to the same structural component or part thereof. Additionally, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

Spatially relative terms, e.g., “beneath,” “below,” “lower,” “above,” “upper,” and the like, can be used herein for ease of description to describe one element or feature's relationship to another element(s) or feature(s) as illustrated in the figures.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the term “about” modifying the quantity of an ingredient, component, or reactant of the disclosure employed refers to variation in the numerical quantity that can occur, for example, through typical measuring procedures used for making component mixtures. Furthermore, variation can occur from inadvertent error in measuring procedures, differences in the manufacture, source, or purity of the ingredients employed to make the compositions or carry out the methods, and the like.

It will also be understood that when an element, such as a layer, region, or substrate is referred to as being “on” or “over” another element, it can be directly on the other element or intervening elements can also be present. In contrast, when an element is referred to as being “directly on” or “directly over” another element, there are no intervening elements present, and the element is in contact with another element.

The ion implantation system and ion implantation processes in accordance with the present disclosure are not intended to be limited provided the liquid metal alloy precursor compositions can be appropriately heated, vaporized, or etched when exposed to a suitable plasma source, and have ions extracted therefrom. Accordingly, the present disclosure will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present disclosure may be practiced without these specific details. Further, the scope of the disclosure is not intended to be limited by the embodiments or examples described hereinafter with reference to the accompanying drawings but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling.

As noted above, the present disclosure is generally directed to liquid metal alloy precursor compositions for use as an ion source for ion implantation. The liquid metal alloy precursor compositions can be heated to form homogenous or heterogenous liquid metal alloy compositions that are subsequently ionized in the ion implantation system.

The homogenous liquid metal alloy compositions generally refer to a homogenous liquid of two or more metals, which form a eutectic melting point below a maximum operating temperature of an ion source suitable for processing liquid metal alloy precursor compositions, which currently is a maximum operating temperature of about 550° C. At temperatures greater than 550° C., the ceramic crucible used to liquefy the precursor composition can fail. The term “eutectic” refers to a melting temperature for the homogenous liquid metal alloy composition that is generally lower than each of the constituents. An exception in the present disclosure are homogenous liquid metal alloy compositions that include a metal that has a relatively low melting point. For example, gallium which by itself has a relatively low melting point of about 30° C., can be used in a liquid metal alloy precursor composition with one or more higher melting temperature metals, wherein the resulting eutectic melting temperature is greater than 30° C. and less than the melting temperature of the higher melting temperature metal. The liquid metal alloy compositions including gallium still exhibit a eutectic melting point relative to the other constituents in the composition, which is a lower melting temperature than that expected based on the weight percentages of the different constituents in the liquid metal alloy precursor compositions.

In the present disclosure, the homogenous liquid metal alloy precursor compositions can include two or more metals in the composition that, when heated and liquified, have a eutectic melting temperature equal to or less than 550° C., which represents a maximum operating temperature used in ion implantation systems including a liquid metal ion source. By way of example, the homogenous liquid metal alloy precursor composition can be a bimetallic eutectic. Exemplary binary homogenous liquid metal alloy precursor compositions and the respective eutectic melting points (m.p.) are shown in Table 1 below. The composition of the eutectics is given as % by weight.

TABLE 1

| | | Melting | | Melting | Eutectic |
|---|---|---|---|---|---|
| | | Point | | Point | Melting |
| | Metal 1 | (° C.) | Metal 2 | (° C.) | Point (° C.) |
| 1. | La (87 wt %) | 920 | Ga (13 wt %) | 30 | 550 |
| 2. | Al (53 wt %) | 660 | Ge (47 wt %) | 938 | 424 |
| 3. | Ag (44 wt %) | 961 | Bi (56 wt %) | 271 | 139 |
| 4. | Al (11 wt %) | 660 | Li (89 wt %) | 180 | 145 |
| 5. | Ag (80 wt %) | 961 | Sn (20 wt %) | 232 | 280 |
| 6. | Al (31 wt %) | 660 | Te (69 wt %) | 450 | 350 |
| 7. | Ag (5 wt %) | 961 | Zn (95 wt %) | 419 | 380 |
| 8. | Al (27 wt %) | 660 | Sr (73 wt %) | 769 | 436 |
| 9. | Ag (65 wt %) | 961 | Mg (35 wt %) | 650 | 450 |
| 10. | Ag (48 wt %) | 961 | Mg (52 wt %) | 650 | 472 |
| 11. | Ag (23 wt %) | 961 | La (77 wt %) | 920 | 518 |
| 12. | Ag (16 wt %) | 961 | Ce (84 wt %) | 795 | 525 |
| 13. | Al (67 wt %) | 660 | Cu (33 wt %) | 1008 | 550 |

As noted above, the homogenous liquid metal alloy compositions can include more than two metals in the composition. The number of metals in the precursor composition is not intended to be limited. An exemplary higher order homogenous liquid metal alloy composition conducive for its use with liquid metal ion sources is tin-bismuth-lanthanum alloy composition having a weight ratio of Sn (58 wt %), Bi (0.5 wt %), La (41.5 wt %), which has a eutectic melting temperature of about 137.8° C. and is suitable for use in ion implantation systems as a liquid metal ion source. Other metal precursor combinations are contemplated so long as the resulting eutectic temperature is less than the maximum operating temperature for the particular ion implantation systems, e.g., operating temperatures typically less than about 550° C.

Heterogenous liquid metal alloy precursor compositions generally refer to heterogenous liquid metal alloy mixtures or dispersions including one or more additive metals that is at least partially suspended in a metal-based solvent, i.e., flux material. By way of example, gallium, which has a relatively low melting temperature of 30° C., can act as a flux material for other metals, i.e., one or more additive metals. The one or more additive metals can be at least partially soluble in liquid gallium, wherein gallium's melting temperature is 30° C. The specific temperature the liquid metal alloy precursor composition is heated above 30° C. will determine a maximum weight percentage of the additive metal(s) that can be incorporated into the gallium flux while providing a homogenous solution. Increasing the amount of the additive metal(s) in the liquid metal alloy precursor composition beyond the solubility limit at the specific temperature results in a heterogenous liquid alloy mixture or dispersion. In some instances, the crystallinity of the additive metal(s) can be affected such that smaller particles result when combined with the flux metal. It has unexpectedly been found that the heterogenous liquid metal alloy mixture or dispersion provides a stable ion beam source when exposed to a plasma source of an ion implantation system.

During ionization of the heterogenous liquid metal alloy ion source, ions of both the flux metal and the one or more additive metals can be extracted and implanted into a semiconductor substrate. The particle sizes of the additive metal in the saturated flux metal alloy composition are generally determined by the diameter of the transfer tube between reservoirs of the particular ion implantation system and the arc chamber as will be discussed in greater detail below, the densities of the flux metal and additive metal at the operating temperature, and the solubility of the additive metal in the flux at the operating temperature of the ion source.

The ion implantation system suitable for use in the present disclosure is not intended to be limited so long as the system is configured to process liquid metal ion sources. Exemplary vacuum systems including suitable ion implantation systems for processing liquid metal ion sources are described in U.S. Pat. No. 11,170,967 to Bassom et al. entitled, Liquid Metal Ion Source, and U.S. Pat. No. 11,728,140 to Bassom et al. entitled, Hydraulic Feed System for an Ion Source, both of which are incorporated by reference in their entireties.

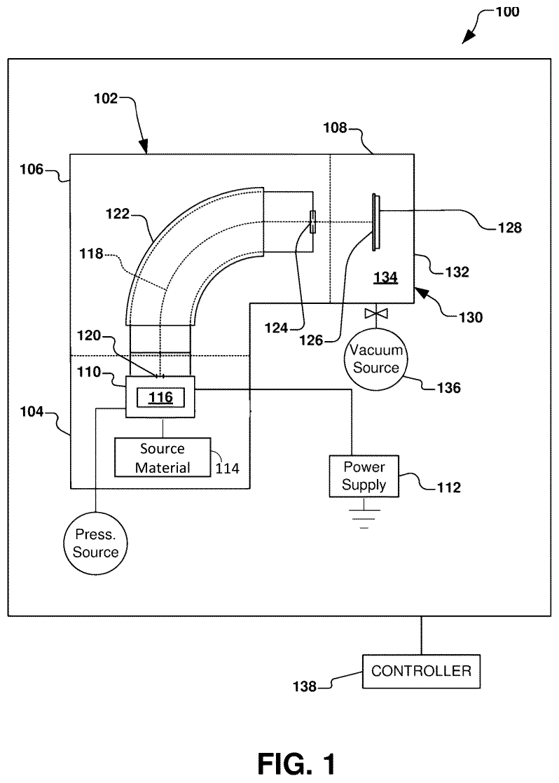

By way of example, FIG. 1 illustrates an exemplary vacuum system 100 including an ion implantation system 102 suitable for liquifying a liquid metal alloy precursor composition and provide a liquid metal alloy ion source, however various other types of vacuum systems are also contemplated, such as plasma processing systems, or other semiconductor processing systems. The ion implantation system 102 generally includes a terminal 104, a beamline assembly 106, and an end station 108.

A liquid metal alloy ion source 110 in the terminal 104 is coupled to a power supply 112, whereby a supply of liquid metal alloy precursor composition 114 is heated to form a liquid as described above and provided to an arc chamber 116 to form the liquid metal alloy ion source 110, wherein the liquid metal alloy ion source 110 is subsequently ionized into a plurality of ions to form and extract an ion beam 118 through an extraction aperture 120. The ion beam 118 in the present example is directed through a beam-steering apparatus 122 (also called an atomic mass unit (AMU) magnet) to select ionized metal elements in the liquid metal alloy ion source, and out an aperture 124 towards the end station 108. In the end station 108, the ion beam 118 bombards a workpiece 126 (e.g., a semiconductor such as a silicon wafer, a display panel, etc.), which is selectively clamped or mounted to a chuck 128 (e.g., an electrostatic chuck or ESC). Once embedded into the lattice of the workpiece 126, the implanted ions change the physical and/or chemical properties of the workpiece. Because of this, ion implantation is used in semiconductor device fabrication, metal finishing, and various applications in materials science research.

The ion beam 118 formed from the liquid metal alloy ion source is not intended to be limited and can take any form, such as a pencil or spot beam, a ribbon beam, a scanned beam, or any other form in which ions are directed toward end station 108, and all such forms are contemplated as falling within the scope of the disclosure,

The end station 108 can include a process chamber 130, such as a vacuum chamber 132, wherein a process environment 134 is associated with the process chamber. The process environment 134 generally exists within the process chamber 130, and in one example, comprises a vacuum produced by a vacuum source 136 (e.g., a vacuum pump) coupled to the process chamber and configured to substantially evacuate the process chamber. Further, a controller 138 is provided for overall control of the vacuum system 100 and components, thereof.

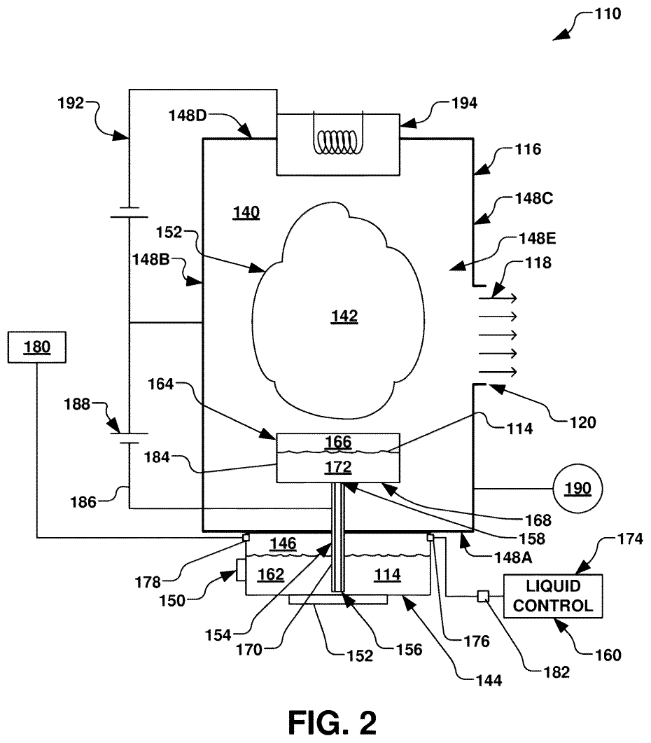

An exemplary are chamber 116 for the liquid metal alloy ion source 110, for example, is schematically illustrated in FIG. 2, whereby the liquid metal alloy ion source 110 of the present disclosure can be configured to provide the ion beam 118 of FIG. 1, whereby a high beam current is attained by supplying the liquid metal alloy precursor composition 114 to the arc chamber 116 in a pure, elemental, and solid form, in a novel manner, as opposed to providing a gaseous compound or solid target, as conventionally seen. For example, in accordance with the present disclosure, the liquid metal alloy precursor composition 114 can be initially provided to the ion source 110 of FIG. 2 in solid form.

As illustrated in FIG. 2, the arc chamber 116 generally defines an are chamber volume 140 in which a plasma 142 is formed from the liquid metal alloy ion source material 114. A reservoir 144 (e.g., a crucible) can be operably coupled to the arc chamber 116, wherein the reservoir generally defines a reservoir volume 146. The reservoir 144, for example, is configured to contain the liquid metal alloy precursor composition 114 in a liquid form within the reservoir volume 146,

The reservoir 144, for example, is further selectively coupled to one or more sidewalls 148A-148E of the arc chamber 116. In the present example, the reservoir 144 can be operably coupled to a selected sidewall 148A-148E of the arc chamber 116, e.g., bottom sidewall 148A of the arc chamber 116, whereby the reservoir can be directly or indirectly coupled to the one or more sidewalls, and can be either stationary or translational with respect to the arc chamber.

The reservoir volume 146, for example, is selectively accessible for selective placement and enclosure of the liquid metal alloy precursor composition 114 (e.g., in solid form), therein. For example, one or more securement apparatuses 150 (e.g., one or more bolts, latches, screws, levers, plates, or other coupling devices) can be provided to selectively access the reservoir volume 146, such as to selectively operably and fluidly couple the reservoir 144 to the arc chamber 116. In the present example, the reservoir 144 can be selectively removed from the arc chamber 116, whereby the liquid metal alloy precursor composition 114 can be placed within the reservoir volume, and then the reservoir can again be coupled to the arc chamber.

A heat source 152 is further provided in thermal communication with the reservoir 144. The heat source 152, in one example, is controllable and configured to selectively heat the reservoir to a predetermined temperature associated with the liquid metal alloy precursor composition 114 being in a liquid state. The predetermined temperature, for example, can be based on the selection of the liquid metal alloy precursor composition 114, whereby the predetermined temperature is at or greater than a melting point of the selected liquid metal alloy precursor composition 114 placed within the reservoir volume 146, i.e., above a eutectic temperature in the case of a homogenous liquid metal alloy precursor composition or above the flux temperature of a metal element in a heterogenous liquid metal alloy precursor composition.

The heat source 152, for example, can include one or more electrical heaters operably coupled to the reservoir 144. The heat source 152 can include any source of heat, such as radiative heat lamps, a heat pump, heat associated with the plasma 142 formed within the arc chamber 116, or any other heating apparatus in thermal communication with the reservoir 144, The reservoir 144, for example, can be thermally coupled to the arc chamber 116, whereby heat associated with the plasma 142 provides heating of the liquid metal alloy precursor composition 114 within the reservoir so as to maintain the liquid metal alloy precursor composition 114 in liquid form at the predetermined temperature. As such, the arc chamber 116, itself, can act as the heat source 152, whereby the formation of the plasma 142 selectively heats the reservoir 144 via thermal conduction through the bottom sidewall 148A of the arc chamber. In some instances, the coupling of the reservoir 144 to the arc chamber 116 can advantageously augment heating provided by the above-described electrical heaters such that the liquid metal alloy precursor composition 114 within the reservoir 144 is heated to, or maintained in, the liquid state.

In accordance with another example, FIG. 2 illustrates a conduit 154 fluidly coupling the reservoir volume 146 to the arc chamber volume 140. For example, the conduit 154 comprises a first opening 156 and a second opening 158, wherein the first opening is operably coupled to the reservoir 144 and open to the reservoir volume 146, and wherein the second opening is vertically elevated from the first opening and open to the are chamber volume 140.

A liquid control apparatus 160, for example, is further operably coupled to the reservoir 144, wherein the liquid control apparatus is configured to control a first volume 162 of the liquid metal alloy precursor composition 114 defined within the reservoir volume 146 when the liquid metal alloy precursor composition is in the liquid state. The control of the first volume 162 of the liquid metal alloy precursor composition 114 in the liquid state within the reservoir volume 146, for example, defines a predetermined supply of the liquid metal alloy precursor composition to the are chamber volume 140 via a transfer of the liquid metal alloy precursor composition from between the first opening 156 and the second opening 158 of the conduit 154. The liquid metal alloy precursor composition 114 is further vaporized within the arc chamber 116 for forming the plasma 142. The liquid metal alloy precursor composition 114, for example, is exposed directly to an arc chamber volume 140,

In one example, a cup 164 is further positioned within the arc chamber 116, wherein the cup defines a cup volume 166 that is generally exposed to the arc chamber volume 140. The second opening 158 of the conduit 154, for example, is defined in a bottom surface 168 of the cup 164 and opens to the cup volume 166, whereby the liquid metal alloy precursor composition in liquid form can be further between the reservoir volume 146 and the cup volume 166 via the liquid control apparatus 160. For example, the cup 164 comprises a stem 170 extending from the bottom surface 168 of the cup through the bottom sidewall 148A of the arc chamber 116, wherein the conduit 154 is defined within the stem, and wherein the reservoir 144 is positioned beneath the cup. The liquid control apparatus 160, for example, thus controls a second volume 172 of the liquid metal alloy precursor composition 114 in liquid form within the cup 164 volume via the control of the first volume 162 of the liquid metal alloy precursor composition within the reservoir volume 146.

The liquid control apparatus 160 can include a pressurized fluid source 174 fluidly coupled to the reservoir 144. The pressurized fluid source 174, for example, can be configured to selectively supply a fluid, such as gas, to the reservoir 144 at a predetermined pressure and/or flow through a feed orifice 176 associated with the reservoir, wherein the pressure in the reservoir 144 defines the first volume 162 of the liquid metal alloy precursor composition 114 in liquid form within the reservoir volume 146. The liquid control apparatus 160, for example, can thus further control the second volume 172 of the liquid metal alloy precursor composition 114 in liquid form within the cup volume 166 via a pressure differential between the pressurized fluid source 174 and a pressure within the arc chamber volume 140. In one embodiment, the fluid supplied by the pressurized fluid source 174 can be an inert gas such as argon or another gas. Alternatively, the pressurized fluid source can be configured to supply any fluid (e.g., a gas or a liquid) that is non-reactive with the liquid metal alloy precursor composition 114 in liquid form and is generally not deleterious to the desired formation and/or composition of the ion beam 118.

A gas bleed orifice 178, for example, can be further provided in association with the reservoir 144, wherein the gas bleed orifice defines a fluid communication between the reservoir volume 146 and an external environment 180. The external environment 180, for example, can be associated with an environment external to the arc chamber 116 or with the arc chamber volume 140 within the arc chamber 116. The gas bleed orifice 178, for example, can be further configured to selectively bleed the gas from the reservoir volume 146 to the external environment 180, thereby controlling the first volume 162 of the liquid metal alloy precursor composition 114 in liquid form within the reservoir volume. As such, a control of the second volume 172 of the liquid metal alloy precursor composition 114 in liquid form within the cup 164 can be further controlled via the pressure differential between the pressurized fluid source 174, the pressure within the arc chamber volume 140, and a flow of the gas through the gas bleed orifice 178,

The gas bleed orifice 178, for example, can be sized to define a predetermined gas conductance between the reservoir volume 146 and the external environment 180. For example, the liquid metal alloy ion source 110 (i.e., the liquid metal alloy precursor composition 114 in liquid form) and/or ion implantation system 102 of FIG. 1 can be configured to have an acceptable tolerance of approximately 1 sccm of additional gas flow into the system before suffering deleterious results due to pressure or material changes in the system. As such, the gas bleed orifice 178 can be sized to provide less than the aforementioned 1 sccm of gas flow to provide the predetermined gas conductance from the reservoir volume 146 and the external environment 180 without resulting in deleterious effects in the remainder of the system.

Accordingly, in the present example, the liquid control apparatus 160 can further comprise a flow controller 182 (e.g., a mass flow controller) configured to control a flow of the gas that is fed into the reservoir volume 146 from the pressurized fluid source 174, whereby the gas is bled through the gas bleed orifice 178. Based on the predetermined gas conductance associated with the gas bleed orifice, the flow controller 182 can thus advantageously control a pressure differential between the reservoir volume 146 and the external environment 180, thus driving a flow of the liquid metal alloy precursor composition 114 in liquid form between the first volume 162 and the second volume 172.

For example, for a given size of the gas bleed orifice 178, the pressure within the reservoir volume 146 is controlled via control of the flow of the gas into the reservoir volume. If the pressure within the reservoir volume 146 is greater than a predetermined acceptable pressure, the flow rate of the gas can be lowered via the flow controller 182, to permit excessive gas to bleed or leak through the bleed orifice 178 until the predetermined acceptable pressure is reached. The vacuum source 136 of FIG. 1, for example, can further remove the excessive gas from the system.

The controller 138, for example, can be further configured to regulate the pressure within the reservoir volume 146 of FIG. 2 and/or regulate the flow of the source material 114 between the first volume 162 and the second volume 172 based on feedback associated with the flow controller 182. Accordingly, the liquid control apparatus 160 can be further controlled to provide a desired amount of the liquid metal alloy precursor composition 114 in liquid form in one or more of the first volume 162 and second volume 172.

The ion implantation system can be further configured to provide removal of the liquid metal alloy precursor composition 114 in liquid form from the second volume 172 within the cup 164 of FIG. 2, whereby halting or lowering the flow rate of the gas via the flow controller 182 can expeditiously empty or transfer the liquid metal alloy ion source 110 from the second volume into the first volume 162 (e.g., over a period of a few seconds), whereby the gas will further freely escape from the reservoir 144 through the bleed orifice 178.

It shall be noted that the present disclosure further contemplates controlling the pressure within the reservoir volume 146 to control the second volume 172 of the liquid metal alloy ion source 110 within the cup 164, whereby the bleed orifice 178 is eliminated, and wherein the pressure is controlled by a pressure controller (not shown) in place of the flow controller 182.

According to another example aspect, the cup 164 can further define, or is a component of, a repeller apparatus 184 operably coupled to the are chamber 116. The repeller apparatus 184, for example, can be negatively biased with respect to the arc chamber 116 by a bias voltage 186 (e.g., 0-500V) provided by a repeller power supply 188. For example, the bias voltage 186 (e.g., a repeller supply voltage) can be altered in response to changes in arc current, extraction current, or other factors for control purposes. The controller 138 of FIG. 1, for example, can control the bias voltage 186, input parameters to the source magnet 122, and/or other parameters associated with the plasma 142 of FIG. 2, whereby an amount of power from the plasma can be controlled and provided to the liquid metal alloy precursor composition 114 in liquid form (i.e., liquid metal alloy ion source 110) within the cup 164, thus raising its temperature high enough for a vapor pressure to sustain the plasma within the arc chamber 116 or increase the material etch rate when using a halide gas. The repeller can also be grounded or positively biased where the resulting increase in electron flow (arc current) can be used to heat the reservoir to the required temperature. The repeller may be set to a lower voltage than that of the cathode.

A support gas 190, for example, can be optionally introduced to the arc chamber 116 to further sustain the plasma 142, whereby the support gas may be inert (e.g., argon) or chemically reactive (e.g., fluorine, chlorine, PF₃) with the source material 114. The support gas 190, for example, can further increase efficiency of the liquid metal alloy ion source 110 by sputtering material or etching material that condenses on one or more walls 148 (also called sidewalls) that generally enclose the arc chamber 116 and convert the sputtered material back into the plasma 142. The bias voltage 186, for example, can be further provided, controlled, or augmented by an arc voltage 192 (e.g., 0-150V) applied to a cathode 194 associated with the arc chamber 116.

Thus, in accordance with various aspects of the disclosure, the heat source 152, including heat associated with the arc chamber 116 of the liquid metal alloy ion source 110 and/or an additional heater, is configured to melt and/or maintain a liquid state of the liquid metal alloy precursor composition 114 including the desired element for ionization in the reservoir 144 that is positioned proximate to the arc chamber, whereby hydrostatic pressure associated with the liquid control apparatus 160 is utilized to introduce the desired element into the arc chamber at a controlled rate. In this manner, material waste is advantageously reduced when a changeover from one ion species to another occurs, as reducing a pressure provided by the liquid control apparatus 160 can relatively quickly control the second volume 172 of liquid metal alloy precursor composition 114 in liquid form that is provided within the are chamber volume 140, as the liquid metal alloy ion source 110 will flow (e.g., by gravity) from the cup 164 through the conduit 154 and back into the reservoir 144, thus depleting the second volume 172 to zero. As such, when it is desired to change operation of the liquid metal alloy ion source 110 from a first species of the liquid metal alloy precursor composition 114 to a second species of source material, wasteful use of the first species from the liquid metal alloy ion source 110 can be avoided, and the output of the second species of a different liquid metal alloy precursor composition 114 can be maximized, as substantially none of the first species from the liquid metal alloy precursor composition 114 will be present in the plasma 142 upon changeover of species.

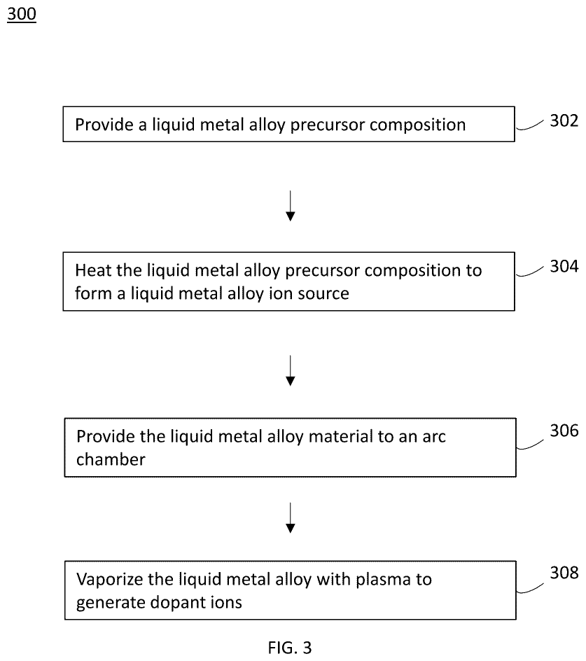

In accordance with another exemplary aspect, a method 300 is provided in FIG. 3 for providing a homogenous or heterogenous liquid metal alloy precursor composition to an ion source for forming an ion beam for an ion implantation into a workpiece. It should be noted that while exemplary methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

It should be noted that the controller 134 of FIG. 1 may be configured to perform the method 300 of FIG. 3, whereby control of various components discussed above may be achieved in the manner described herein. As illustrated in FIG. 3, the exemplified method 300 begins at step 302, wherein a homogenous or heterogenous liquid metal alloy precursor composition, such as a combination of metals in elemental form, is provided to an ion source in solid form. The composition can be in a powder or other solid form. The particle size is not intended to be limited and in the case of heterogenous liquid metal precursor compositions is generally limited by the dimensions of the transfer tube to the arc chamber. Generally, the metals in powder form can have a mesh size of 10 to 1000 and have a monodisperse or polydisperse distribution. The composition, for example, is provided to a cup of a reservoir apparatus positioned inside an are chamber, as described above.

In step 304, the homogenous or heterogenous liquid metal alloy precursor composition is heated to a liquid state, and in step 306, the liquefied metal is provided to an interior region of the arc chamber. Steps 304 and 306 may be performed sequentially or concurrently in various orders. In one example, the homogenous or heterogenous liquid metal alloy precursor composition may be heated to the liquid state external to the arc chamber in step 304 and subsequently provided to the interior region of the arc chamber instep 306. In step 308, the liquid metal alloy ion source is vaporized to form a plasma.

As an example, gallium was employed as a flux material for a heterogenous liquid metal alloy precursor composition. In the gallium flux, metal particles such as aluminum (Al), lanthanum (La), cerium (Ce), platinum (Pt), neodymium (Nd), samarium (Sm), europium (Eu), terbium (Tb), dysprosium (Dy), holmium (Ho), erbium (Er) or ytterbium (Yb) with a mesh size of 10-1000 were dispersed under vacuum at room temperature. After increasing the temperature to about 300-550° C., the dispersion was pneumatically transferred to a receiver in the ion implantation system and exposed to an ion source plasma, resulting in a stable ion current, which was unexpected given that the liquid metal ion source was a heterogenous liquid metal alloy composition and included particles.

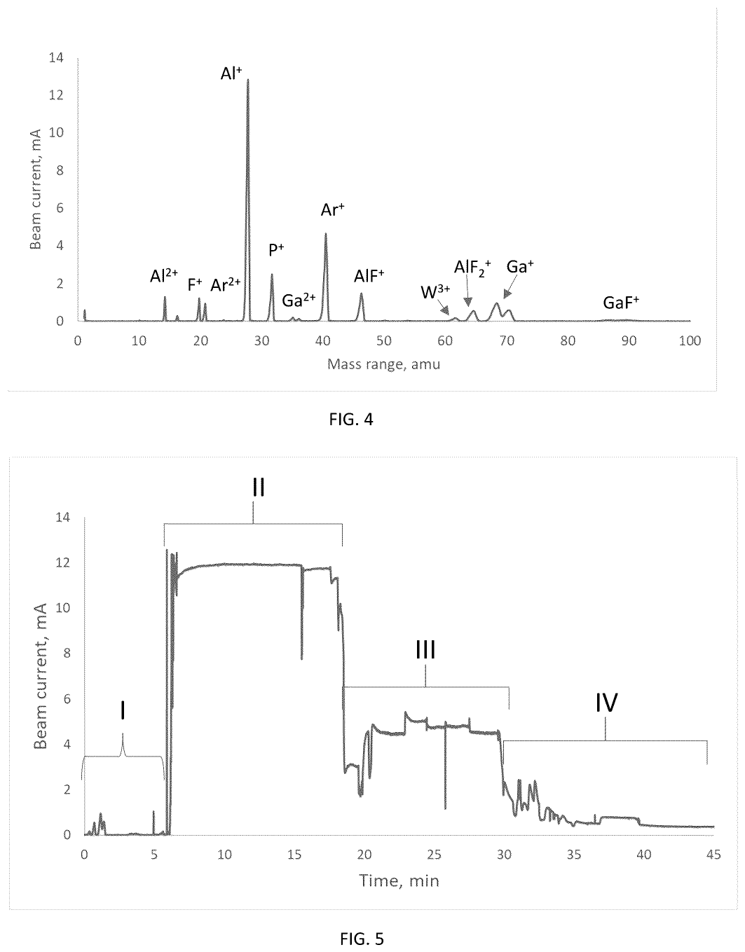

FIG. 4 graphically illustrates mass peaks as a function of relative beam current for a heterogenous aluminum-gallium alloy ion source mixture with PF₃ at an arc current of 2.5 A and an arc voltage of 140V. FIG. 5 graphically illustrates beam current as a function of the mass ranges depicting different elements generated from the aluminum-gallium heterogenous mixture through steps I-IV as a function of time. In stage I, a heterogenous aluminum-gallium alloy ion source mixture containing 10 grams of aluminum and 2 grams of gallium in powder form was placed in a container and heated with an argon flow rate of 4 standard cubic centimeters per minute (sccm). Heating elements on the side of the container were heated to 540° C. and heating elements at the bottom of the container were heated to 400° C. Because this was a heterogenous mixture, the amount of aluminum was greater than the solubility limit in gallium at the specified temperature of the container. The heterogenous mixture was then flowed into the arc chamber of an ion implantation system as generally described above with an argon flow rate of 2 sccm, an arc current of 2.5 Amps, and an arc voltage of 140V. In stage II, the argon gas flow was discontinued and phosphorous trifluoride was introduced as a chemical etchant into the arc chamber at a flow rate of 2.5 sccm at a pressure of 10 Torr, the arc current of 2.5 Amps, and the arc voltage of 140V. In stage III, the phosphorous trifluoride was discontinued, and argon was flowed into the arc chamber to remove residues at a flow rate of 2 sccm, an arc current of 3 Amps and the arc voltage of 140V. Argon continued to flow into the container at a flow rate of 4 sccm. In stage IV, the cup was drained, which included discontinuing the flow of argon to the container. As shown, the ion beam was stable.

The foregoing descriptions of the preferred embodiments of the disclosure have been presented for purposes of illustration and description. It is not intended to be exhaustive or to limit the disclosure to the precise forms disclosed. Obvious modifications or variations are possible in light of the above teachings. The embodiments were chosen and described to provide the best illustration of the principles of the disclosure and its practical applications to thereby enable one of ordinary skill in the art to utilize the disclosure in various embodiments and with various modifications as are suited to the particular use contemplated. All such modifications and variations are within the scope of the disclosure as determined by the appended claims when interpreted in accordance with the breadth to which they are fairly, legally and equitably entitled.

What is claimed:

1. A process for implanting ions into a workpiece using a liquid metal alloy ion source, the process comprising:
heating a liquid metal precursor composition at an operating temperature of less than about 550° C. to form a homogeneous or heterogenous liquid metal alloy ion source;
vaporizing and ionizing the homogeneous or heterogenous liquid metal alloy ion source in an arc chamber to create a plasma of ionized metal elements;
extracting the ionized metal elements within the plasma through a source aperture to form an ion beam; and
implanting one or more of the ionized metal elements into the workpiece.

2. The process of claim 1, wherein the liquid metal alloy precursor composition comprises a metal alloy mixture of two or more metals having a eutectic melting temperature at the operating temperature of less than about 550° C.

3. The process of claim 1, wherein the liquid metal alloy precursor comprises a mixture of two or more metals, wherein at least one of the metals is selected from the group consisting of aluminum (Al), lanthanum (La), cerium (Ce), platinum (Pt), neodymium (Nd), germanium (Ge), bismuth (Bi), silver (Ag), lead (Pb), lithium (Li), tellurium (Te), zinc (Zn), strontium (Sr) magnesium (Mg), gold (Au), copper (Cu) samarium (Sm), europium (Eu), terbium (Tb), dysprosium (Dy), holmium (Ho), erbium (Er) ytterbium (Yb), gallium (Ga), indium (In), tin (Sn), and selenium (Se).

4. The process of claim 1, wherein the liquid metal alloy precursor composition forms a heterogenous liquid metal alloy at the operating temperature comprising a flux metal having a relatively low melting point and one or more additive metals soluble in the flux metal having a relatively higher melting point, wherein the one or more additive metals are in an amount exceeding a solubility limit in the flux metal at the operating temperature of the arc chamber.

5. The process of claim 1, wherein the liquid metal alloy precursor composition forms a homogenous liquid metal alloy at the operating temperature comprising two or more metals selected to provide a eutectic melting temperature of less than about 550° C., wherein at least one of the metals has a melting point greater than the eutectic melting temperature.

6. The process of claim 1, wherein the liquid metal alloy precursor composition is in a powder or other solid form.

7. The process of claim 1, wherein the heterogenous liquid metal alloy ion source comprises a flux metal and at least one additional metal at least partially soluble therein.

8. The process of claim 7, further comprising mass analyzing the ion beam to permit selected ionized mass metal elements to pass therethrough; and implanting selected ionized mass elements into the workpiece.

9. The process of claim 1, wherein the homogenous liquid metal alloy composition comprises a binary composition of lanthanum (La) and gallium (Ga); aluminum (Al) and germanium (Ge); lead (Pb) and bismuth (Bi); silver (Ag) and one of lithium (Li), tellurium (Te), strontium (Sr), magnesium (Mg), lanthanum (La), or cerium (Ce); gold (Au) and tin (Sn); or aluminum (Al) and one of zinc (Zn), magnesium (Mg) or copper (Cu).

10. The process of claim 1, wherein the homogenous liquid metal alloy precursor composition comprises tin (Sn), bismuth (Bi), and lanthanum (La).

11. A liquid metal alloy precursor composition as an ion source for ion implantation comprising two or more metals having a eutectic melting point less than about 550° C. configured to form a homogeneous liquid metal alloy ion source in an arc chamber of the ion implantation system at an operating temperature greater than the eutectic melting temperature, vaporize, and ionize in a plasma source into a plurality of dopant ions.

12. The liquid metal alloy precursor composition of claim 11, wherein the two or more metals comprise of lanthanum (La) and gallium (Ga); aluminum (Al) and germanium (Ge); lead (Pb) and bismuth (Bi); silver (Ag) and one of lithium (Li), tellurium (Te), strontium (Sr), magnesium (Mg), lanthanum (La), or cerium (Ce); gold (Au) and tin (Sn); or aluminum (Al) and one of zinc (Zn), magnesium (Mg) or copper (Cu).

13. The liquid metal alloy precursor composition of claim 11, wherein at least one of the two or more metals is selected from the group consisting of aluminum (Al), lanthanum (La), cerium (Ce), platinum (Pt), neodymium (Nd), germanium (Ge), bismuth (Bi), silver (Ag), lead (Pb), lithium (Li), tellurium (Te), zinc (Zn), strontium (Sr) magnesium (Mg), gold (Au), copper (Cu) samarium (Sm), europium (Eu), terbium (Tb), dysprosium (Dy), holmium (Ho), erbium (Er) ytterbium (Yb), gallium (Ga), indium (In), tin (Sn), and selenium (Se).

14. The liquid metal alloy precursor composition of claim 11, wherein the at least two or more metals comprise aluminum (Al), magnesium (Mg) and copper (Cu).

15. The liquid metal alloy precursor composition of claim 11, wherein the two or more metals are in powder or other solid form.

16. A liquid metal alloy precursor composition as an ion source for ion implantation comprising a first metal and at least one additional metal configured to form a heterogeneous liquid metal alloy ion source in an arc chamber of an ion implantation system, vaporize, and ionize in a plasma source into a plurality of dopant ions, wherein the first metal is a liquid flux metal and the at least one additional metal is at least partially soluble in the liquid flux metal at an operating temperature of a crucible containing the liquid metal alloy precursor composition, wherein the operating temperature is less than about 550° C. and is above a melting temperature of the first metal.

17. The liquid metal alloy precursor composition of claim 16, wherein the first metal is gallium.

18. The liquid metal alloy precursor composition of claim 16, wherein the at least one additional metal is selected from the group consisting of aluminum (Al), lanthanum (La), cerium (Ce), platinum (Pt), neodymium (Nd), germanium (Ge), bismuth (Bi), silver (Ag), lead (Pb), lithium (Li), tellurium (Te), zinc (Zn), strontium (Sr) magnesium (Mg), gold (Au), copper (Cu) samarium (Sm), europium (Eu), terbium (Tb), dysprosium (Dy), holmium (Ho), erbium (Er) ytterbium (Yb), indium (In), tin (Sn), and selenium (Se).

19. The liquid metal alloy precursor composition of claim 16, wherein the liquid metal alloy precursor composition is in a powder or other solid form prior to being heated at the operating temperature of the crucible.

20. The liquid metal alloy precursor composition of claim 16, wherein the first metal is gallium and the at least one additional metal is aluminum.
